(19) United States
(12) Patent Application Publication
(10) Pub. No.: US 2016/0330866 A1
(43) Pub. Date: Nov. 10, 2016

(54) LIQUID COOLING SYSTEM

(71) Applicant: COOLER MASTER TECHNOLOGY INC., New Taipei City (TW)

(72) Inventor: Chia-Hsiang Chi, New Taipei City (TW)

(21) Appl. No.: 14/706,000

(22) Filed: May 7, 2015

(51) Int. Cl. H05K 7/20

(52) U.S. Cl. CPC H05K 7/20272

(57) ABSTRACT

A liquid cooling system includes a liquid cooling head, a radiator, a pump and a plurality of tubes. The tubes are connected between the liquid cooling head, the radiator and the pump and used for transporting a cooling liquid between the liquid cooling head, the radiator and the pump. At least one of the liquid cooling head, the radiator and the tubes includes a temperature sensitive color-changing material, such that the at least one of the liquid cooling head, the radiator and the tubes is capable of changing color in accordance with temperature variance of the cooling liquid.

### BACKGROUND OF THE INVENTION

1. Field of the Invention

The invention relates to a liquid cooling system and, more particularly, to a liquid cooling system equipped with a liquid cooling head, a radiator and/or a tube capable of changing color in accordance with temperature variance of a cooling liquid.

2. Description of the Prior Art

In general, a liquid cooling system essentially consists of a liquid cooling head, a radiator, a pump and a liquid storage box connected through a plurality of tubes. When the liquid cooling system is dissipating heat from an electronic component, the pump transports a cooling liquid to the liquid cooling head, the cooling liquid absorbs the heat generated by the electronic component, and then the radiator cools the cooling liquid. If the liquid cooling system cannot dissipate the heat generated by the electronic component in time, the electronic component may be damaged due to over-heat. So far a user cannot directly determine whether the liquid cooling system is working normally from the appearance of the liquid cooling system, such that the user cannot determine whether the temperature of the electronic component is too high and then proceed with corresponding operation in time. Accordingly, the conventional liquid cooling system is inconvenient in use.

### SUMMARY OF THE INVENTION

The invention provides a liquid cooling system equipped with a liquid cooling head, a radiator and/or a tube capable of changing color in accordance with temperature variance of a cooling liquid, so as to solve the aforesaid problems.

According to an embodiment of the invention, a liquid cooling system comprises a liquid cooling head, a radiator, a pump and a plurality of tubes. The tubes are connected between the liquid cooling head, the radiator and the pump and used for transporting a cooling liquid between the liquid cooling head, the radiator and the pump. At least one of the liquid cooling head, the radiator and the tubes comprises a temperature sensitive color-changing material, such that the at least one of the liquid cooling head, the radiator and the tubes is capable of changing color in accordance with temperature variance of the cooling liquid.

As mentioned in the above, the invention can selectively add the temperature sensitive color-changing material to the liquid cooling head, the radiator and/or the tubes, such that the liquid cooling head, the radiator and/or the tubes is/are capable of changing color in accordance with temperature variance of the cooling liquid. Accordingly, a user can directly determine whether the liquid cooling system is working normally from the appearance of the liquid cooling system, such that the user can determine whether the temperature of the electronic component is too high and then proceed with corresponding operation in time.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a liquid cooling system according to an embodiment of the invention.

FIG. 2 is a schematic view illustrating the liquid cooling head shown in FIG. 1 with changed color.

FIG. 3 is a schematic view illustrating a liquid storage unit of the radiator shown in FIG. 1 with changed color.

FIG. 4 is a schematic view illustrating the tube shown in FIG. 1 with changed color.

FIG. 5 is a schematic view illustrating another tube shown in FIG. 1 with changed color.

FIG. 6 is a schematic view illustrating another tube shown in FIG. 1 with changed color.

FIG. 7 is a schematic view illustrating a liquid cooling system according to another embodiment of the invention.

FIG. 8 is a schematic view illustrating the liquid storage box shown in FIG. 7 with changed color.

### DETAILED DESCRIPTION

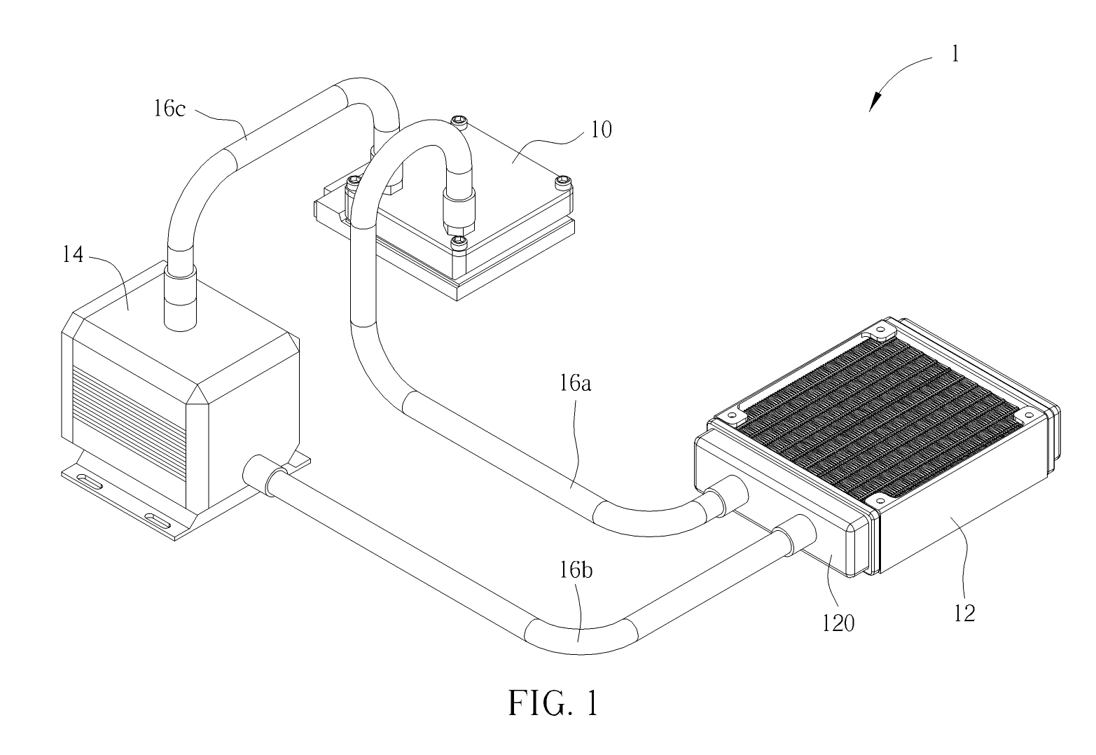

Referring to FIG. 1, FIG. 1 is a schematic view illustrating a liquid cooling system 1 according to an embodiment of the invention. As shown in FIG. 1, the liquid cooling system 1 comprises a liquid cooling head 10, a radiator 12, a pump 14 and a plurality of tubes 16a, 16b, 16c. The tubes 16a, 16b, 16c are connected between the liquid cooling head 10, the radiator 12 and the pump 14 and used for transporting a cooling liquid between the liquid cooling head 10, the radiator 12 and the pump 14. The cooling liquid (not shown in FIG. 1) is filled in the liquid cooling head 10, the radiator 12, the pump 14 and the tubes 16a, 16b, 16c. When the liquid cooling system 1 of the invention is used for dissipating heat from an electronic component (not shown), the liquid cooling head 10 of the liquid cooling system 1 is attached on the electronic component. The pump 14 transports the cooling liquid to the liquid cooling head 10, the cooling liquid absorbs the heat generated by the electronic component, and then the radiator 12 cools the cooling liquid. In practical applications, the cooling liquid may be water or other liquids.

In this embodiment, at least one of the liquid cooling head 10, the radiator 12 and the tubes 16a, 16b, 16c comprises a temperature sensitive color-changing material, such that the at least one of the liquid cooling head 10, the radiator 12 and the tubes 16a, 16b, 16c is capable of changing color in accordance with temperature variance of the cooling liquid. The temperature sensitive color-changing material may be temperature sensitive color-changing dye, temperature sensitive color-changing ink or other temperature sensitive color-changing materials. In general, the temperature sensitive color-changing material may generate two or more than two colors in accordance with temperature variance and it depends on practical applications.

Therefore, when the cooling liquid absorbs the heat generated by the electronic component and the temperature thereof is raised, at least one of the liquid cooling head 10, the radiator 12 and the tubes 16a, 16b, 16c will change color in accordance with temperature variance of the cooling liquid. Accordingly, a user can directly determine whether the liquid cooling system 1 is working normally from the appearance of the liquid cooling head 10, the radiator 12 and/or the tubes 16a, 16b, 16c, such that the user can determine whether the temperature of the electronic component is too high and then proceed with corresponding operation in time.

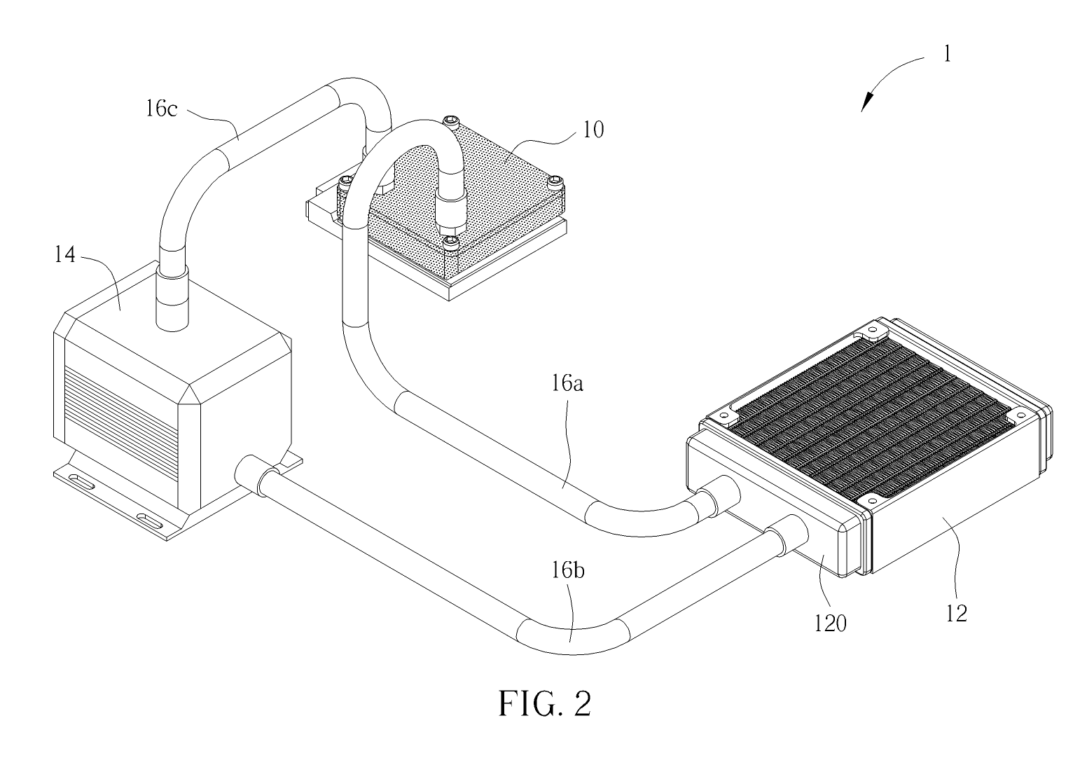

Referring to FIG. 2, FIG. 2 is a schematic view illustrating the liquid cooling head 10 shown in FIG. 1 with changed color. According to the invention, the temperature sensitive color-changing material may be doped in or coated on a casing of the liquid cooling head 10, such that the liquid cooling head 10 is capable of changing color in accordance with temperature variance of the cooling liquid. For example, when the temperature sensitive color-changing material is temperature sensitive color-changing dye, the temperature sensitive color-changing material may be doped in the casing of the liquid cooling head 10 through an injection molding process; and when the temperature sensitive color-changing material is temperature sensitive color-changing ink, the temperature sensitive color-changing material may be coated on the casing of the liquid cooling head 10 through a printing process. Therefore, when the cooling liquid absorbs the heat generated by the electronic component and the temperature thereof is raised, the liquid cooling head 10 will change color in accordance with temperature variance of the cooling liquid, as shown in FIG. 2.

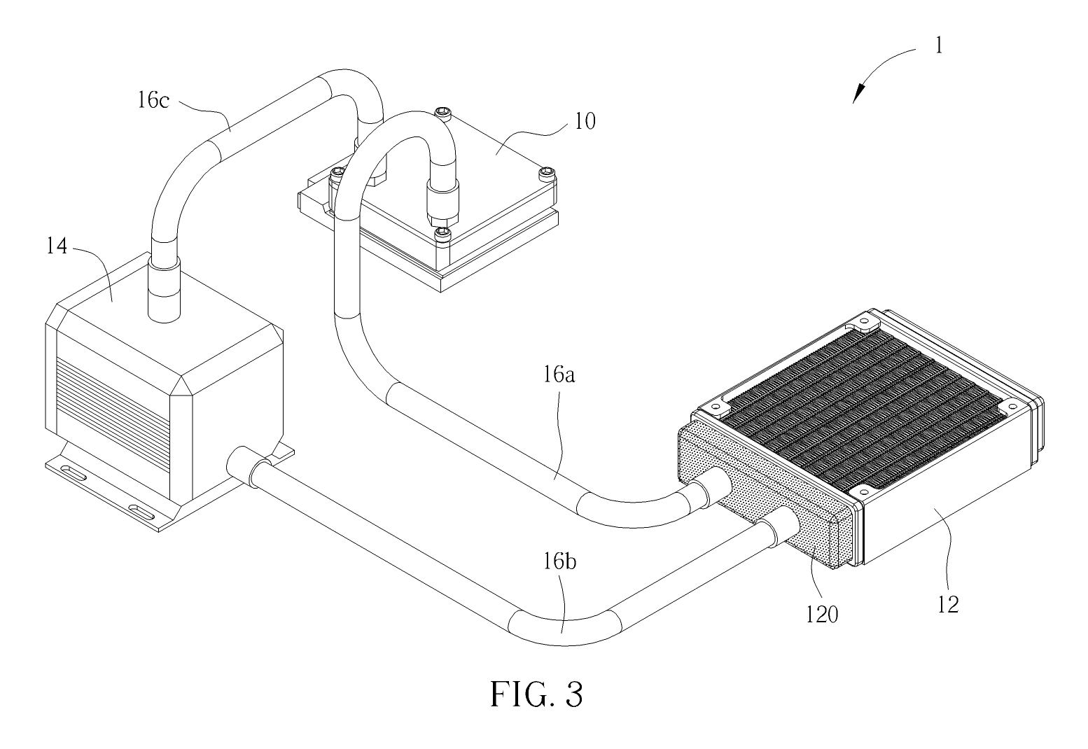

Referring to FIG. 3, FIG. 3 is a schematic view illustrating a liquid storage unit 120 of the radiator 12 shown in FIG. 1 with changed color. In this embodiment, the radiator 12 may comprise a liquid storage unit 120. According to the invention, the temperature sensitive color-changing material may be doped in or coated on a casing of the liquid storage unit 120, such that the liquid storage unit 120 is capable of changing color in accordance with temperature variance of the cooling liquid. For example, when the temperature sensitive color-changing material is temperature sensitive color-changing dye, the temperature sensitive color-changing material may be doped in the casing of the liquid storage unit 120 through an injection molding process; and when the temperature sensitive color-changing material is temperature sensitive color-changing ink, the temperature sensitive color-changing material may be coated on the casing of the liquid storage unit 120 through a printing process. Therefore, when the cooling liquid absorbs the heat generated by the electronic component and the temperature thereof is raised, the liquid storage unit 120 of the radiator 12 will change color in accordance with temperature variance of the cooling liquid, as shown in FIG. 3.

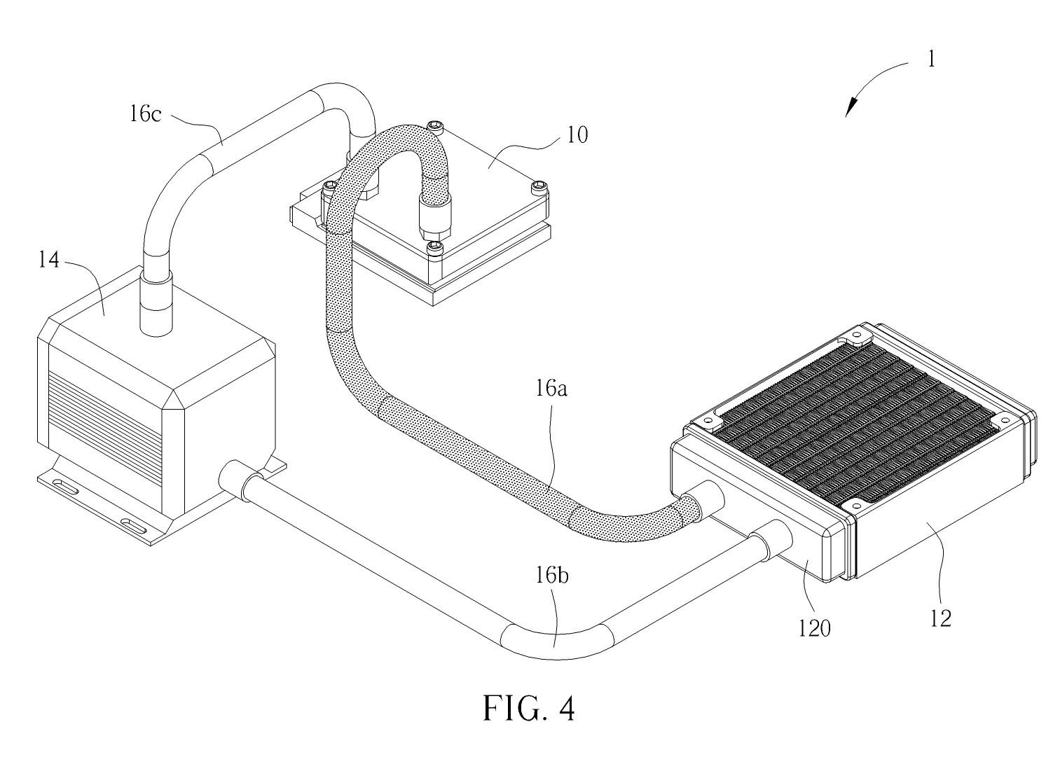

Referring to FIG. 4, FIG. 4 is a schematic view illustrating the tube 16a shown in FIG. 1 with changed color. In this embodiment, the tube 16a of the tubes 16a, 16b, 16c maybe a color-changing tube, wherein the color-changing tube 16a is connected between the liquid cooling head 10 and the radiator 12. According to the invention, the temperature sensitive color-changing material may be doped in or coated on a tube body of the color-changing tube 16a, such that the color-changing tube 16a is capable of changing color in accordance with temperature variance of the cooling liquid. For example, when the temperature sensitive color-changing material is temperature sensitive color-changing dye, the temperature sensitive color-changing material may be doped in the tube body of the color-changing tube 16a through an injection molding process; and when the temperature sensitive color-changing material is temperature sensitive color-changing ink, the temperature sensitive color-changing material may be coated on the tube body of the color-changing tube 16a through a printing process. Therefore, when the cooling liquid absorbs the heat generated by the electronic component and the temperature thereof is raised, the color-changing tube 16a will change color in accordance with temperature variance of the cooling liquid, as shown in FIG. 4.

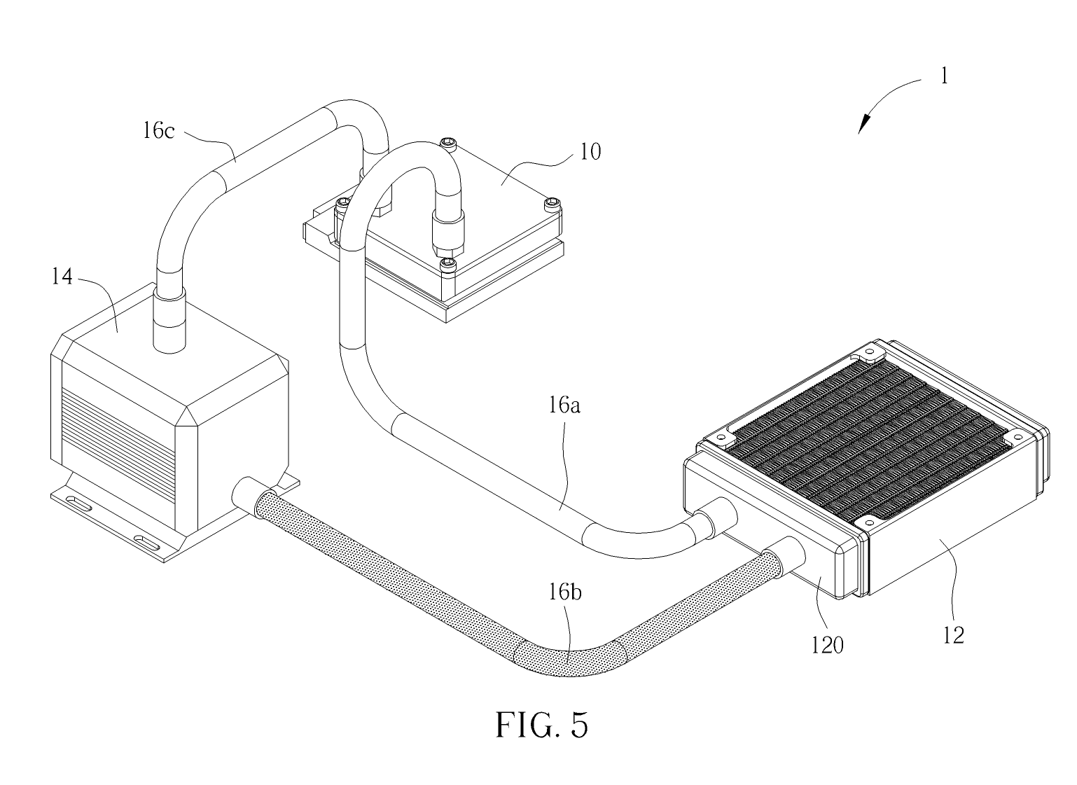

Referring to FIG. 5, FIG. 5 is a schematic view illustrating another tube 16b shown in FIG. 1 with changed color. In this embodiment, the tube 16b of the tubes 16a, 16b, 16c may be a color-changing tube, wherein the color-changing tube 16b is connected between the radiator 12 and the pump 14. According to the invention, the temperature sensitive color-changing material may be doped in or coated on a tube body of the color-changing tube 16b, such that the color-changing tube 16b is capable of changing color in accordance with temperature variance of the cooling liquid. For example, when the temperature sensitive color-changing material is temperature sensitive color-changing dye, the temperature sensitive color-changing material may be doped in the tube body of the color-changing tube 16b through an injection molding process; and when the temperature sensitive color-changing material is temperature sensitive color-changing ink, the temperature sensitive color-changing material may be coated on the tube body of the color-changing tube 16b through a printing process. Therefore, when the cooling liquid maintains high temperature after passing through the radiator 12, the color-changing tube 16b will change color in accordance with temperature variance of the cooling liquid, as shown in FIG. 5. When the color-changing tube 16b changes color, it means that the heat dissipating function of the radiator 12 maybe abnormal. At this time, the user can replace or repair the radiator 12 in time, so as to prevent the electronic component from being damaged due to over-heat.

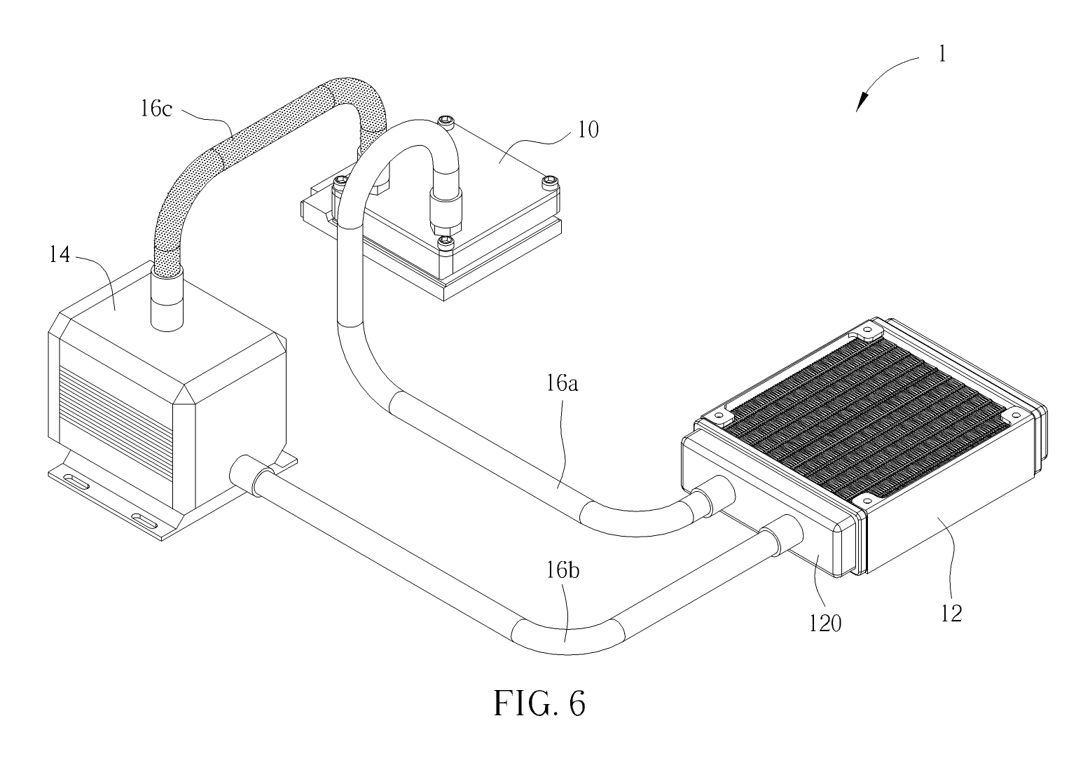

Referring to FIG. 6, FIG. 6 is a schematic view illustrating another tube 16c shown in FIG. 1 with changed color. In this embodiment, the tube 16c of the tubes 16a, 16b, 16c may be a color-changing tube, wherein the color-changing tube 16c is connected between the pump 14 and the liquid cooling head 10. According to the invention, the temperature sensitive color-changing material maybe doped in or coated on a tube body of the color-changing tube 16c, such that the color-changing tube 16c is capable of changing color in accordance with temperature variance of the cooling liquid. For example, when the temperature sensitive color-changing material is temperature sensitive color-changing dye, the temperature sensitive color-changing material may be doped in the tube body of the color-changing tube 16c through an injection molding process; and when the temperature sensitive color-changing material is temperature sensitive color-changing ink, the temperature sensitive color-changing material may be coated on the tube body of the color-changing tube 16c through a printing process. Therefore, when the cooling liquid maintains high temperature after passing through the radiator 12, the color-changing tube 16c will change color in accordance with temperature variance of the cooling liquid, as shown in FIG. 6. When the color-changing tube 16c changes color, it means that the heat dissipating function of the radiator 12 maybe abnormal. At this time, the user can replace or repair the radiator 12 in time, so as to prevent the electronic component from being damaged due to over-heat.

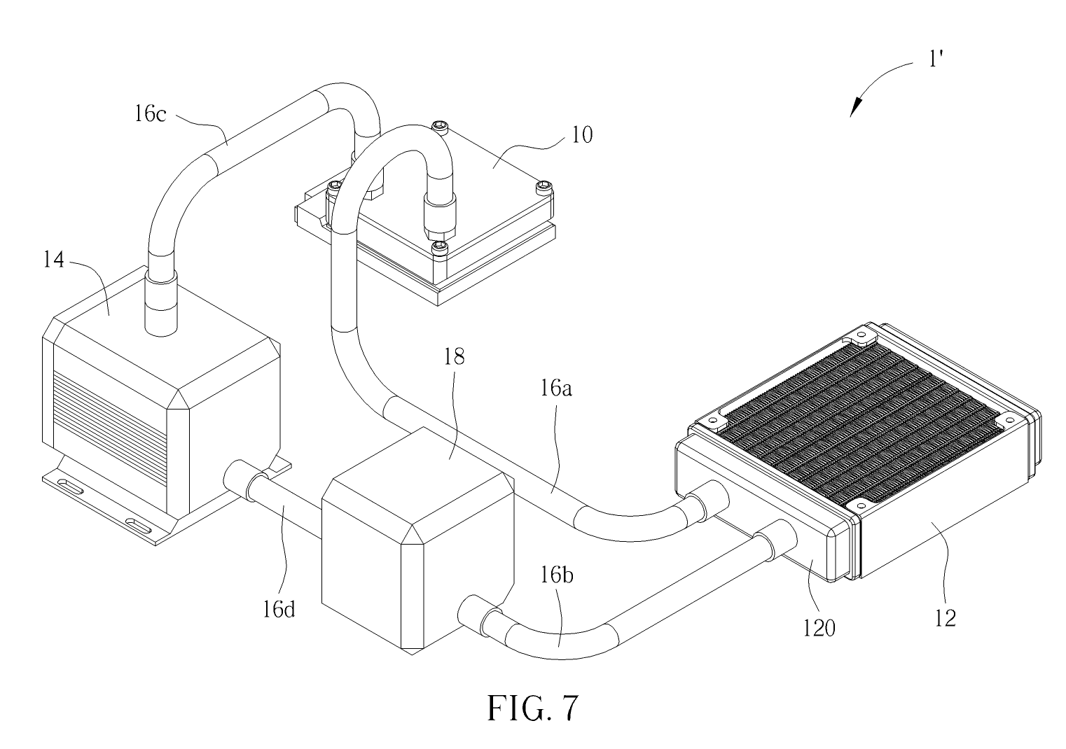

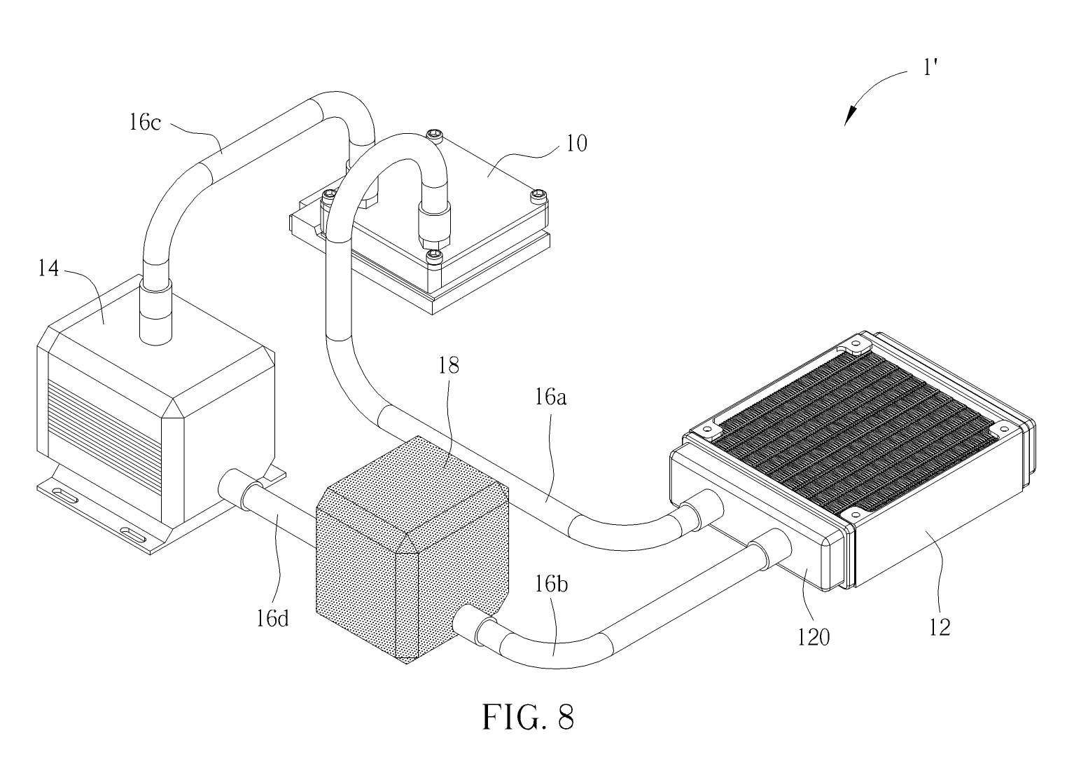

Referring to FIGS. 7 and 8, FIG. 7 is a schematic view illustrating a liquid cooling system 1′ according to another embodiment of the invention, and FIG. 8 is a schematic view illustrating the liquid storage box 18 shown in FIG. 7 with changed color. The difference between the liquid cooling system 1′ and the aforesaid liquid cooling system 1 is that the liquid cooling system 1′ further comprises a liquid storage box 18 connected between the radiator 12 and the pump 14 through the tubes 16b, 16d, as shown in FIG. 7. The liquid storage box 18 is used for storing the cooling liquid. According to the invention, the temperature sensitive color-changing material may be doped in or coated on a casing of the liquid storage box 18, such that the liquid storage box 18 is capable of changing color in accordance with temperature variance of the cooling liquid. For example, when the temperature sensitive color-changing material is temperature sensitive color-changing dye, the temperature sensitive color-changing material may be doped in the casing of the liquid storage box 18 through an injection molding process; and when the temperature sensitive color-changing material is temperature sensitive color-changing ink, the temperature sensitive color-changing material maybe coated on the casing of the liquid storage box 18 through a printing process. Therefore, when the cooling liquid maintains high temperature after passing through the radiator 12, the liquid storage box 18 will change color in accordance with temperature variance of the cooling liquid, as shown in FIG. 8. When the liquid storage box 18 changes color, it means that the heat dissipating function of the radiator 12 maybe abnormal. At this time, the user can replace or repair the radiator 12 in time, so as to prevent the electronic component from being damaged due to over-heat.

As mentioned in the above, the invention can selectively add the temperature sensitive color-changing material to the liquid cooling head, the radiator, the tubes and/or the liquid storage box, such that the liquid cooling head, the radiator, the tubes and/or the liquid storage box is/are capable of changing color in accordance with temperature variance of the cooling liquid. Accordingly, a user can directly determine whether the liquid cooling system is working normally from the appearance of the liquid cooling system, such that the user can determine whether the temperature of the electronic component is too high and then proceed with corresponding operation in time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid cooling system comprising:
a liquid cooling head;
a radiator;
a pump; and
a plurality of tubes connected between the liquid cooling head, the radiator and the pump and used for transporting a cooling liquid between the liquid cooling head, the radiator and the pump;
wherein at least one of the liquid cooling head, the radiator and the tubes comprises a temperature sensitive color-changing material, such that the at least one of the liquid cooling head, the radiator and the tubes is capable of changing color in accordance with temperature variance of the cooling liquid.

2. The liquid cooling system of claim 1, wherein the temperature sensitive color-changing material is doped in or coated on a casing of the liquid cooling head, such that the liquid cooling head is capable of changing color in accordance with temperature variance of the cooling liquid.

3. The liquid cooling system of claim 1, wherein the radiator comprises a liquid storage unit and the temperature sensitive color-changing material is doped in or coated on a casing of the liquid storage unit, such that the liquid storage unit is capable of changing color in accordance with temperature variance of the cooling liquid.

4. The liquid cooling system of claim 1, wherein one of the tubes is a color-changing tube and the temperature sensitive color-changing material is doped in or coated on a tube body of the color-changing tube, such that the color-changing tube is capable of changing color in accordance with temperature variance of the cooling liquid.

5. The liquid cooling system of claim 4, wherein the color-changing tube is connected between the liquid cooling head and the radiator.

6. The liquid cooling system of claim 4, wherein the color-changing tube is connected between the radiator and the pump.

7. The liquid cooling system of claim 4, wherein the color-changing tube is connected between the pump and the liquid cooling head.

8. The liquid cooling system of claim 1, further comprising a liquid storage box connected between the radiator and the pump through the tubes.

9. The liquid cooling system of claim 8, wherein the temperature sensitive color-changing material is doped in or coated on a casing of the liquid storage box, such that the liquid storage box is capable of changing color in accordance with temperature variance of the cooling liquid.
